(19) United States
(12) Patent Application Publication
(10) Pub. No.: US 2014/0003177 A1
(43) Pub. Date: Jan. 2, 2014

(54) Memory Device, System Having the Same, and Method for Manufacturing the Same

(71) Applicant: JEONG In Chul, Suwon-si (KR)

(72) Inventor: JEONG In Chul, Suwon-si (KR)

(21) Appl. No.: 13/827,079

(22) Filed: Mar. 14, 2013

(30) Foreign Application Priority Data
Jul. 2, 2012 (KR) 10-2012-0071991

(51) Int. Cl. G11C 7/06

(52) U.S. Cl. CPC G11C 7/06
USPC 365/207

(57) ABSTRACT

A memory device includes a memory cell array including normal memory cells arranged in a form of matrix, and a sense amplifier array including sense amplifiers each amplifying a signal output from each of the normal memory cells. Some of the sense amplifiers have different sizes so that they may have different sense capabilities depending on a layout location. The size is determined according to at least one of a channel length and a channel width of a MOS transistor included in each of the some sense amplifiers.

### CROSS-REFERENCE TO RELATED APPLICATIONS

This application claims priority under 35 U.S.C. §119(a) from Korean Patent Application No. 10-2012-0071991 filed on Jul. 2, 2012, the disclosure of which is hereby incorporated by reference in its entirety.

### BACKGROUND

Sense amplifiers in semiconductor memory devices are typically used for read operations in order to determine the logical value stored by a cell in a selected row of a memory cell array. Often, sense amplifiers are arranged in an array pattern, or in one or more rows that include edge sense amplifiers on ends of the row(s) or array, and inner sense amplifiers that are located between edge sense amplifiers. In manufacturing sense amplifier arrays, there is typically some small variation in the structure of different elements of the sense amplifiers due to process variation. The variation in edge sense amplifiers of a sense amplifier array, however, tends to be greater than the variation in inner sense amplifiers of the array. This may lead to sensing errors and problems in operational performance.

### SUMMARY

In one embodiment, a memory device includes a memory cell array including memory cells arranged in a matrix; and a sense amplifier array including a plurality of sense amplifiers, each sense amplifier configured to amplify a signal output from each cell of a set of memory cells. Each sense amplifier of the sense amplifier array is formed of a plurality of transistors, and an average size among the plurality of transistors that form a first sense amplifier of the sense amplifier array is larger than an average size among the plurality of transistors that form a second sense amplifier of the sense amplifier array.

In one embodiment, the first sense amplifier is an edge sense amplifier, and the second sense amplifier is an inner sense amplifier.

In one embodiment, an average channel length among the plurality of transistors that form the first sense amplifier of the sense amplifier array is larger than an average channel length among the plurality of transistors that form the second sense amplifier of the sense amplifier array.

In another embodiment, an average channel width among the plurality of transistors that form the first sense amplifier of the sense amplifier array is larger than an average channel width among the plurality of transistors that form the second sense amplifier of the sense amplifier array.

An average size among the plurality of transistors that form a third sense amplifier of the sense amplifier array may be substantially the same as the average size among the plurality of transistors that form the second sense amplifier of the sense amplifier array. The first sense amplifier may be an edge sense amplifier, while the second and third sense amplifiers are inner sense amplifiers.

In one embodiment, an average channel area among the plurality of transistors that form the first sense amplifier of the sense amplifier array is larger than an average channel area among the plurality of transistors that form the second sense amplifier of the sense amplifier array.

In one embodiment, the average channel area among the plurality of transistors that form the first sense amplifier of the sense amplifier array is at least 10% larger than the average channel area among the plurality of transistors that form the second sense amplifier of the sense amplifier array.

In a further embodiment, a memory device includes a memory cell array including memory cells arranged in rows and columns; and a sense amplifier array including a plurality of sense amplifiers, each sense amplifier configured to amplify a signal output from at least part of a column of memory cells. Each sense amplifier of the sense amplifier array is formed of a plurality of transistors, and a difference in average size between the plurality of transistors that form a first sense amplifier of the sense amplifier array and the plurality of transistors that form a second sense amplifier of the sense amplifier array is greater than a difference in average size between the plurality of transistors that form the second sense amplifier of the sense amplifier array and the plurality of transistors that form a third sense amplifier of the sense amplifier array.

The first sense amplifier may be an edge sense amplifier while the second and third sense amplifiers are each inner sense amplifiers.

In one embodiment, the first sense amplifier is adjacent the second sense amplifier. The second sense amplifier may be adjacent the third sense amplifier.

In one embodiment, the difference in average size between the plurality of transistors that form the first sense amplifier of the sense amplifier array and the plurality of transistors that form the second sense amplifier of the sense amplifier array is due to one or more of: average channel length of the plurality of transistors that form the first sense amplifier being different from average channel length of the plurality of transistors that form the second sense amplifier; and average channel width of the plurality of transistors that form the first sense amplifier being different from average channel width of the plurality of transistors that form the second sense amplifier.

In one embodiment, the difference in average size between the plurality of transistors that form the first sense amplifier of the sense amplifier array and the plurality of transistors that form the second sense amplifier of the sense amplifier array is at least 10%.

In one embodiment, a memory device includes a memory cell array including normal memory cells arranged in a matrix; and a sense amplifier array including sense amplifiers each configured to amplify a signal output from each memory cell of a set of the normal memory cells. A first set of the sense amplifiers have different sizes than a second set of the sense amplifiers, so that different sense amplifiers have different sensing capabilities based on a layout location.

The memory device of claim 15, wherein the sizes of the sense amplifiers of the first set may differ from the sizes of the sense amplifiers of the second set according to at least one of a channel length and a channel width of a MOS transistor included in each of the respective sense amplifiers.

In one embodiment, the sense amplifier array includes two edge sense amplifiers, each located at an edge of the sense amplifier array, and inner sense amplifiers located between the edge sense amplifiers, wherein an average element size of a set of first amplification elements included in each of the edge sense amplifiers, is greater than an average element size of a set of second amplification elements included in each of the inner sense amplifiers.

The average element size of the set of first amplification elements may be greater than the average element size of the set of second amplification elements, for example, by more than 10%.

In one embodiment, the average element size of the set of first amplification elements and the average element size of the set of second amplification elements vary according to channel lengths of at least one of an N-channel MOS transistor and a P-channel MOS transistor included in a corresponding sense amplifier.

The average element size of the set of first amplification elements and the average element size of the set of second amplification elements may vary according to channel widths of at least one of an N-channel MOS transistor and a P-channel MOS transistor included in a corresponding sense amplifier.

The memory device may further include dummy sense amplifiers embodied outside the sense amplifier array.

In one embodiment, the memory cell array is part of three-dimensionally stacked memory cell arrays, the arrays in the stack connected to each other through vertical electrical connectors.

In certain embodiments, the memory device is a semiconductor chip or a semiconductor package.

In one embodiment, the memory device further includes a printed circuit board (PCB) that is part of a memory module, wherein the memory device is mounted on the PCB.

The memory module may be one of single in-line memory module (SIMM), a dual in-line memory module (DIMM), a single in-line pin package (SIPP) memory, and a small outline DIMM (SO-DIMM).

In further embodiments, a system is disclosed. The system includes a memory device, and a memory controller for controlling the memory device. The memory device comprises: a memory cell array including normal memory cells arranged in a matrix; and

a sense amplifier array including sense amplifiers each amplifying a signal output from each cell of a set of normal memory cells. An average element size of first amplification elements, which are included in each of sense amplifiers laid out at edges of the sense amplifier array, is greater than an average element size of second amplification elements, which are included in each of the remaining sense amplifiers of the sense amplifier array.

In one embodiment, a size of the first amplification elements and a size of the second amplification elements differ from each other according to at least one of a channel length and a channel width of at least one of an N-channel MOS transistor and a P-channel MOS transistor included in a corresponding sense amplifier among the sense amplifiers.

The system may be a system on chip (SoC), and/or may comprise a processor including the memory controller, wherein the processor controls performance of at least one of web-browsing, e-mail access, video playback, document editing and image editing.

The system may further include an antenna, and a modem interfacing data transmitted or received between the antenna and the processor, wherein the system is a mobile computing device.

The system may be a multi-chip module, which includes a first chip including the memory device and a second chip including the memory controller.

In other embodiments, a method of manufacturing a memory device is disclosed. The method includes forming a memory cell array including first normal memory cells and second normal memory cells; and forming at the same time, edge sense amplifiers each having a first statistic attribute to amplify a signal output from certain of the first normal memory cells and inner sense amplifiers each having a second statistic attribute to amplify a signal output from certain of the second normal memory cells.

In one embodiment, the first statistic attribute includes a first average channel length of MOS transistors included in the edge sense amplifiers, the second statistic attribute includes a second average channel length of MOS transistors included in the inner sense amplifiers, and the first average channel length is longer than the second average channel length.

In one embodiment, the first statistic attribute includes a first average channel width of MOS transistors included in the edge sense amplifiers, the second statistic attribute includes a second average channel width of MOS transistors included in the inner sense amplifiers, and the first average channel width is wider than the second average channel width.

### BRIEF DESCRIPTION OF THE DRAWINGS

FIG. 1 is a plan view of a wafer including a memory device according to an example embodiment;

FIG. 2A is a block diagram illustrating an example embodiment of the memory device illustrated in FIG. 1;

FIG. 2B is a block diagram illustrating another example embodiment of the memory device illustrated in FIG. 1;

FIG. 3 is a plan view illustrating an example embodiment of a sense amplifier array illustrated in FIG. 2A or 2B;

FIG. 4 is a plan view illustrating another example embodiment of the sense amplifier array illustrated in FIG. 2A or 2B;

FIG. 5 is a plan view illustrating still another example embodiment of the sense amplifier array illustrated in FIG. 2A or 2B;

FIG. 6 is a part of a memory device including an edge sense amplifier included in the sense amplifier array illustrated in FIG. 3, 4, or 5, according to one example embodiment;

FIGS. 7A and 7B illustrate a cross-sectional diagram of N-channel MOS transistors included in the sense amplifier array illustrated in FIG. 3, according to one example embodiment;

FIGS. 8A and 8B illustrate a cross-sectional diagram of N-channel MOS transistors included in the sense amplifier array illustrated in FIG. 4, according to one example embodiment;

FIGS. 9A and 9B illustrate a cross-sectional diagram of N-channel MOS transistors included in the sense amplifier array illustrated in FIG. 5, according to one example embodiment;

FIGS. 10 through 20 are example embodiments of a system including the memory device illustrated in FIG. 2A or 2B; and

FIG. 21 is a flowchart illustrating a method of manufacturing the memory device illustrated in FIG. 2A or 2B, according to one example embodiment.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. Unless indicated otherwise, these terms are only used to distinguish one element from another. For example, a first chip could be termed a second chip, and, similarly, a second chip could be termed a first chip without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures have schematic properties, and shapes of regions shown in figures exemplify specific shapes of regions of elements, and the specific properties and shapes do not limit aspects of the invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Embodiments disclosed herein relate to a semiconductor device, and more particularly, to a memory device including a sense amplifier array, a system having the same, and a method for manufacturing the same.

The memory device includes a memory cell array for storing data, and an access control circuit for controlling an access operation, e.g., a write operation or a read operation, on the memory cell array.

The access control circuit includes decoding circuits decoding address signals, sense-amplifiers sensing and amplifying data stored in memory cells of the memory cell array based on signals output from the decoding circuits, transmission lines transmitting signals output from the sense amplifiers, and output drivers outputting signals transmitted through the transmission lines.

To read correctly data stored in memory cells of a memory cell array, attributes of sense amplifiers should have certain characteristics.

As used herein, ‘process variation’ refers to naturally occurring variation according to attributes, e.g., a channel length, a channel width, and/or oxide thickness, of an element, e.g., a transistor, when manufacturing a memory device, e.g., an integrated circuit. Process variation may cause circuit elements to vary slightly from their designed shape, size, structure, etc. Due to process variation, certain operations carried out by an element may be affected. In some cases, therefore, process variation can cause a semiconductor device to behave in an unpredictable or undesirable manner. As described further below, in some embodiments, certain circuit elements can be designed to have intentionally different characteristics from other elements (e.g., a larger size), to counteract the effects of process variation, particularly in edge sense amplifiers.

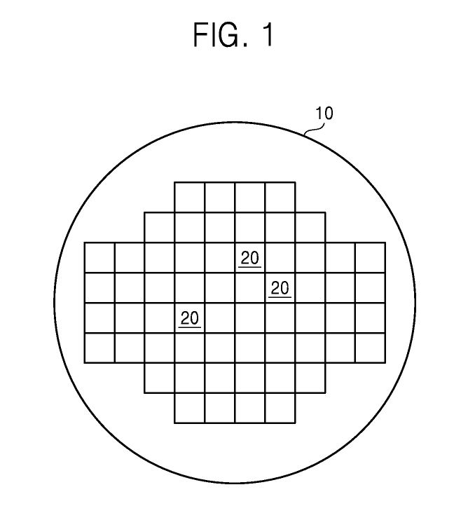

FIG. 1 is a plan view of a wafer including a memory device according to an example embodiment. Referring to FIG. 1, a wafer 10 includes a plurality of memory devices, e.g., a plurality of memory chips 20. Here, a memory device 20 may be called a die.

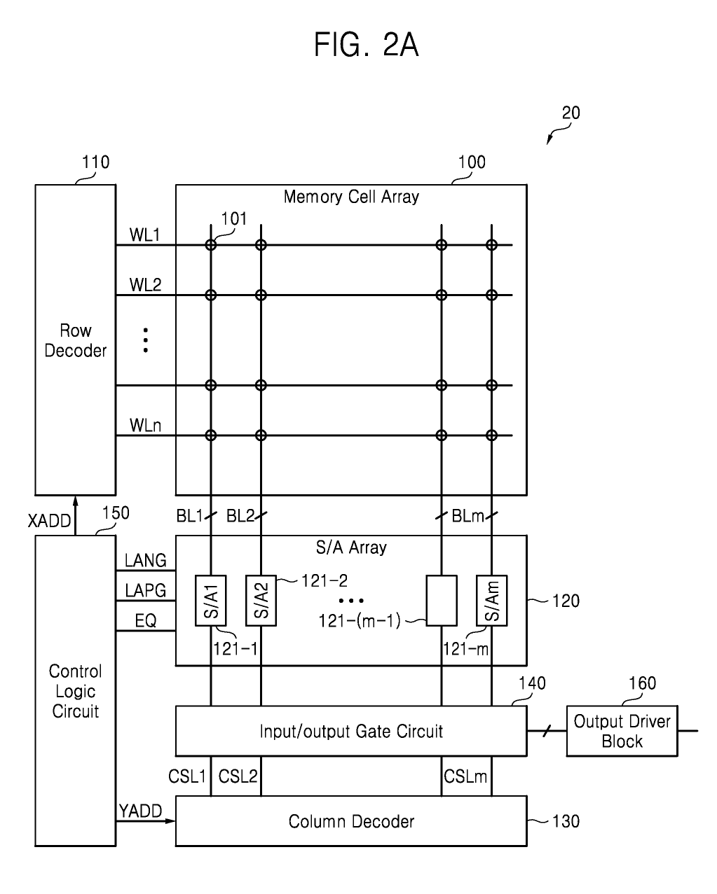

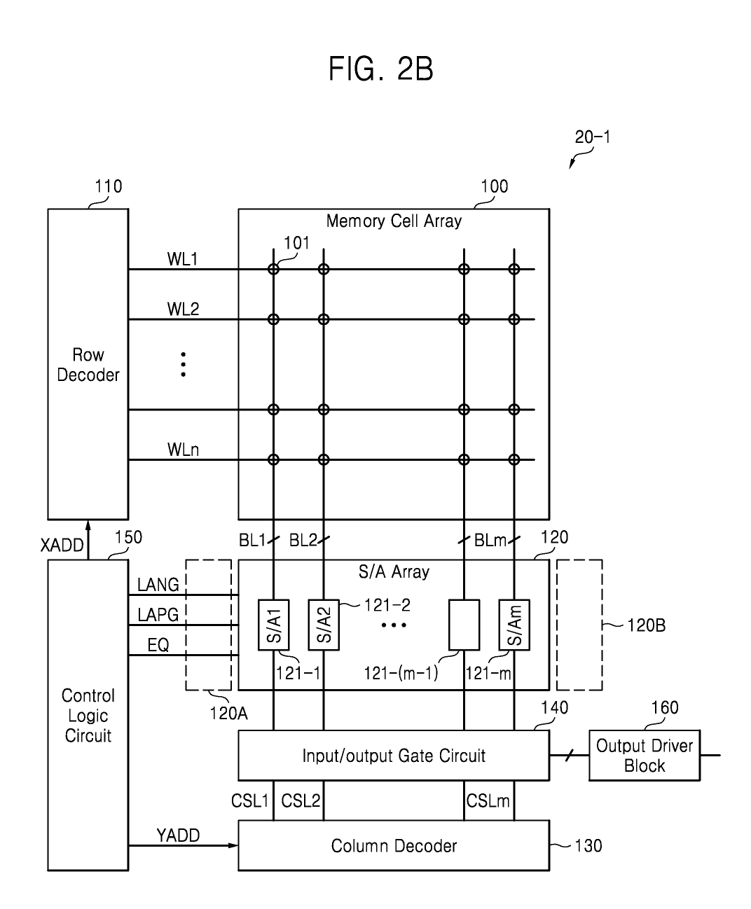

FIG. 2A is a block diagram illustrating an example embodiment of the memory device illustrated in FIG. 1.

The memory device 20 includes a memory cell array 100, a row decoder 110, a sense amplifier array 120, a column decoder 130, an input/output gate circuit 140, a control logic circuit 150, and an output driver block 160.

The memory cell array 100 includes normal memory cells 101 arranged in a form of matrix. Each of the normal memory cells 101 is connected to one of word lines WL1 to WLn, where n is a natural number, and one of bit lines BL1 to BLm, where m is a natural number.

The normal memory cell is distinguished from a redundant memory cell for replacing a defective memory cell. For example, the memory cell array 100 is distinguished from a redundant memory cell array including a redundant memory cell.

Each of the bit lines BL1 to BLm may include a bit line and a complementary bit line.

Each of the normal memory cells 101 may be embodied in a volatile memory cell or a non-volatile memory cell.

A volatile memory cell may be embodied, for example, in a dynamic random access memory (DRAM), a static random access memory (SRAM), a thyristor RAM (T-RAM), a zero capacitor RAM (Z-RAM), or a twin transistor RAM (TTRAM).

A non-volatile memory cell may be embodied, for example, in an electrically erasable programmable read-only memory (EEPROM), a flash memory, a magnetic RAM (MRAM), a spin-transfer torque MRAM, a conductive bridging RAM (CBRAM), a ferroelectric RAM (FeRAM), a Phase change RAM (PRAM), a resistive RAM (RRAM), a Nanotube RRAM, a polymer RAM (PoRAM), a Nano floating gate memory (NFGM), a holographic memory, a molecular electronics memory device, or an insulator resistance change memory. The non-volatile memory cell may store one bit or more.

The row decoder 110 may decode a row address XADD, and activate a corresponding word line among the word lines WL1 to WLn or supply a word line voltage to the corresponding word line based on a decoding result.

A sense amplifier array 120 includes sense amplifiers 121-1 through 121-m embodied in a form of an array. Each of the sense amplifiers 121-1 to 121-m may sense and amplify a signal output from a set of the normal memory cells 101. For example, in one embodiment, each sense amplifier can sense and amplify signals output through one of the bit lines BL1 to BLm. Here, each of the sense amplifiers 121-1 through 121-m is a sense amplifier configured for normal operation, and can be distinguished from a dummy sense amplifier embodied in other regions, such as regions outside a region in which the normally operating sense amplifiers are located. In one embodiment, dummy sense amplifiers do not operate but may have the same structure as the sense amplifiers 121-1 through 121-m (e.g., they may include the same transistor structure, but without being electrically connected to other circuitry).

According to an example embodiment, each of the sense amplifiers 121-1 to 121-m may be embodied in a differential sense amplifier.

A column decoder 130 may decode a column address YADD and generate column selection signals CSL1 to CSLm based on a decoding result. Based on the column selection signals CSL1 to CSLm, an input/output gate circuit 140 may control connection between the sense amplifiers 121-1 to 121-m embodied in the sense amplifier array 120 and output drivers (not shown) embodied in an output driver block 160.

A control logic circuit 150 may generate control signals, e.g., XADD, YADD, LANG, LAPG and EQ used for an access operation, e.g., a write operation or a read operation, on the memory cell array 100.

FIG. 2B is a block diagram illustrating another example embodiment of the memory device illustrated in FIG. 1. Except for a plurality of dummy sense amplifier regions 120A and 120B, a structure and an operation of the memory device 20 illustrated in FIG. 2A are substantially the same as a structure and an operation of a memory device 20-1 illustrated in FIG. 2B.

A dummy sense amplifier region 120A including at least one dummy sense amplifier is embodied at the left side of the sense amplifier array 120, and a dummy sense amplifier region 120B including at least one dummy sense amplifier is embodied at the right side of the sense amplifier array 120.

At least one dummy sense amplifier embodied in each of the plurality of dummy sense amplifier regions 120A and 120B is embodied to secure uniformity of pattern of the normal sense amplifiers 121-1 to 121-m embodied in the sense amplifier array 120.

Accordingly, at least one dummy sense amplifier embodied in each of the plurality of dummy sense amplifier regions 120A and 120B does not operate normally, unlike the normal sense amplifiers 121-1 to 121-m embodied in the sense amplifier array 120. As such, the at least one dummy sense amplifier may not perform a sense amplification operation.

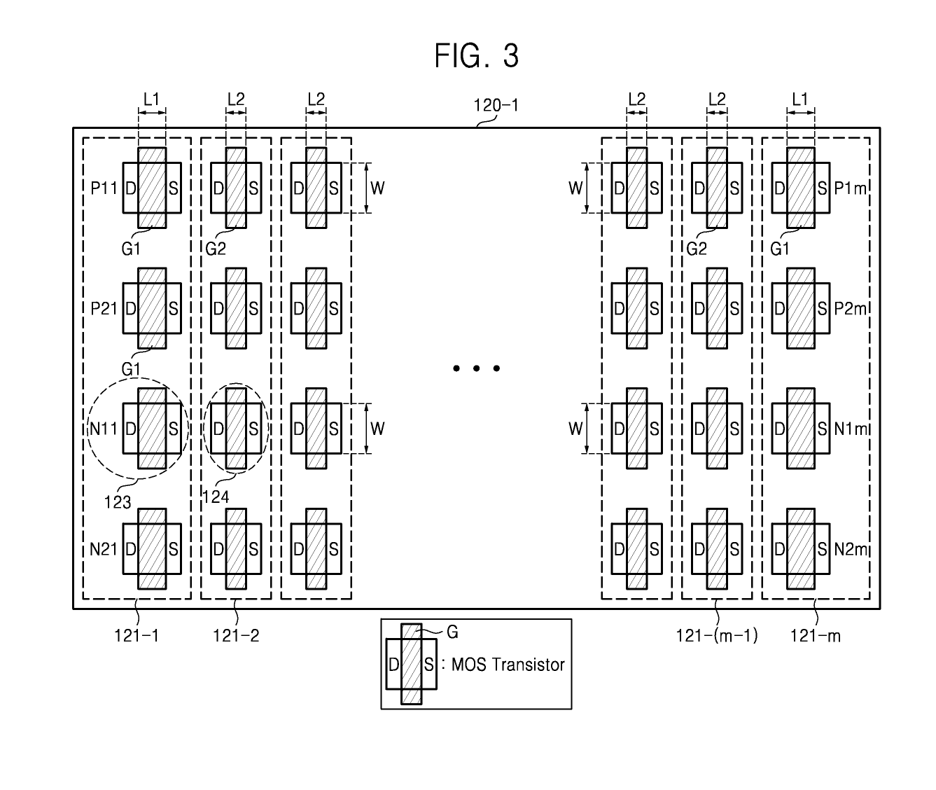

FIG. 3 is a plan view illustrating an example embodiment of the sense amplifier array illustrated in FIG. 2A or 2B. Some of sense amplifiers 121-1 to 121-m are embodied so that they may have different characteristics (e.g., different sizes) to have different sensing capabilities according to layout location (e.g., sense amplifier 121-1 may have different characteristics from sense amplifier 121-2, and sense amplifier 121-(m-1) may have different characteristics from sense amplifier 121-m.

A size of a sense amplifier as discussed herein may refer to a layout size of the sense amplifier. For example, in one embodiment, a size of a sense amplifier is determined based on the channel length of at least one MOS transistor included in the sense amplifier and/or the channel width of at least one MOS transistor included in the sense amplifier.

As illustrated in FIG. 3, in one embodiment, an average size of one or more first amplification elements included in each of sense amplifiers 121-1 and 121-m (hereinafter referred to as “edge sense amplifiers”) laid out or embodied at both edges of a sense amplifier array 120-1 is greater than an average size of one or more second amplification elements included in each of the rest of the sense amplifiers of the array (hereinafter referred to as ‘inner sense amplifiers).

For example, an average size of one or more first amplification elements may be greater than an average size second amplification elements by more than 10%.

The one or more first amplification elements or the one or more second amplification elements may include at least one P-channel MOS transistor and at least one N-channel MOS transistor. In addition, the first amplification element or the second amplification element may mean a sense amplifier itself according to an example embodiment. For example, each sense amplifier of a sense amplifier array may include a plurality of transistors configured to form the sense amplifier. In certain sense amplifiers (e.g., inner sense amplifiers) the transistors that form the sense amplifier may have a first average size (e.g., average size per transistor based on the sizes of all of the transistors that form the sense amplifier). In other sense amplifiers (e.g., edge sense amplifiers) the transistors that form the sense amplifier may have a second average size (e.g., average size per transistor based on the sizes of all of the transistors that form the sense amplifier). As described below, the first size may be different from the second size (e.g., smaller).

In order for the different sense amplifiers to have different sizes, in one embodiment, attributes (e.g., channel length, channel width, and/or oxide thickness) of MOS transistors included in each of the edge sense amplifiers 121-1 and 121-m are embodied to be intentionally different from attributes (e.g., channel length, channel width and/or oxide thickness) of MOS transistors included in each of the inner sense amplifiers 121-2 to 121-(m-1). For example, the attributes can be made significantly different to counteract larger process variations where they occur.

For convenience of explanation, it is illustrated in FIG. 3 that the number of the edge sense amplifiers 121-1 to 121-m is two; however, the number may be four or more according to an example embodiment. For example the closest two sense amplifiers to each edge of the sense amplifier array 120-1 may include the intentionally different sizes. In other embodiments, there may be multiple rows of sense amplifier arrays within a memory device, and each row may include edge sense amplifiers.

In one embodiment, each of the edge sense amplifiers 121-1 and 121-m has substantially the same structure and layout, and each of the inner sense amplifiers 121-2 to 121-(m-1) has substantially the same structure and layout. Moreover, in one embodiment, channel width W of each MOS transistor included in each sense amplifier 121-1 to 121-m is substantially the same. Here, ‘substantially the same’ may mean identity where process variation is considered.

In one embodiment, an average value of channel length (or length of a gate electrode corresponding to the channel length) of each MOS transistor P11, P21, N11, N21, P1m, P2m, N1m, N2m, included in each of the edge sense amplifiers 121-1 and 121-m, i.e., a first average value L1, is greater than an average value of channel length (or length of a gate electrode corresponding to the channel length) of each MOS transistor, which is included in each of the inner sense amplifiers 121-2 to 121-(m-1), i.e., a second average value L2. For example, the transistors P11, P21, N11, and N21 that make up a first edge sense amplifier 121-1 may have a first average channel length among those transistors, and the transistors that make up a first inner sense amplifier 121-2 may have a second average channel length among those transistors. The first channel length may be greater than the second channel length. Alternatively, or additionally, when the entire sense amplifier array is taken as a whole, the average channel length per transistor for all of the transistors that form the edge sense amplifiers may be greater than the average channel length per transistor for all of the transistors that form the inner sense amplifiers.

In one embodiment, the first average value L1 may be greater than the second average value L2 by 10% or more. The value of 10% is exemplary only. In certain embodiments, an intentional average value difference may be selected to be an amount greater than any expected process variation, to ensure that all edge sense amplifiers have greater average channel length than all inner sense amplifiers. For example, the above value of 10% may be used when a known process variation is as high as +/−4%. However, should a known process variation only cause variations of, for example, +/−2%, then an intentional average size increase less than 10% may be used (e.g., 5%). In one embodiment, each transistor of the edge sense amplifiers 121-1 to 121-m has a larger size than any transistor of the inner sense amplifiers 121-2 to 121-(m-1), by the designated percentage (e.g., 10%). In one embodiment, a design parameter may be set such that even after process variations are accounted for, the average values, or the transistor sizes discussed above in the edge sense amplifiers are at least a certain percentage (e.g., 10%) larger than the average values or transistor sizes of the inner sense amplifiers.

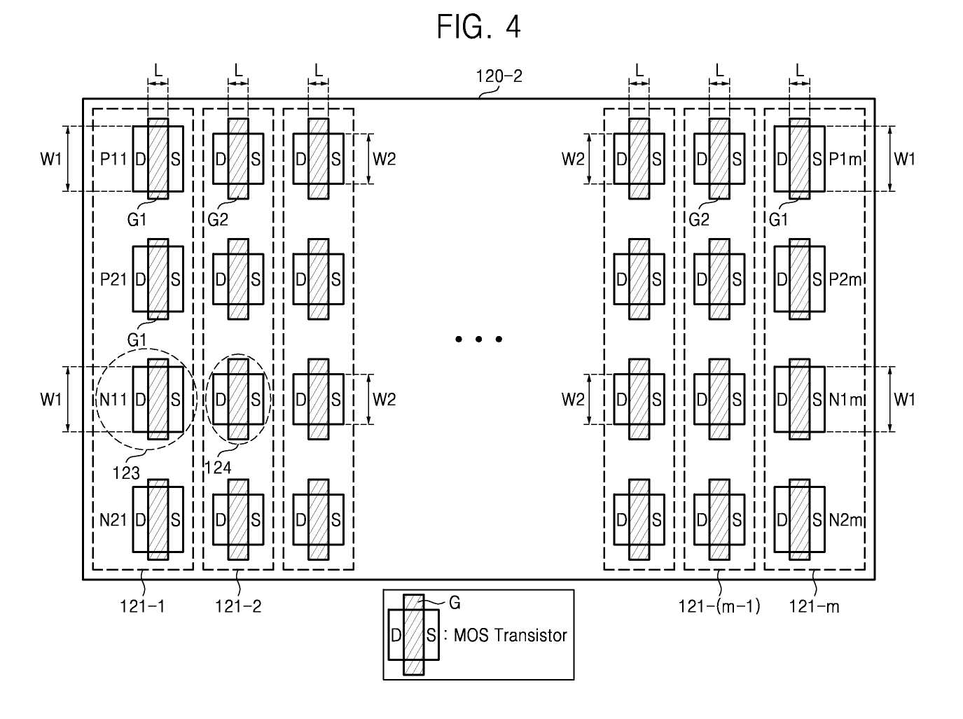

FIG. 4 is a plan view illustrating another example embodiment of a sense amplifier array illustrated in FIG. 2A or 2B. For convenience of explanation, it is illustrated in FIG. 4 that the number of the edge sense amplifiers 121-1 and 121-m is two; however, it can be four or more according to other example embodiments.

In a sense amplifier array 120-2, each of the edge sense amplifiers 121-1 and 121-m has substantially the same layout and structure, and each of the inner sense amplifiers 121-2 to 121-(m-1) has substantially the same layout and structure. Additionally, channel length L of each MOS transistor included in each sense amplifier 121-1 to 121-m is substantially the same. Here, ‘substantially the same’ may mean identity where a process variation is considered.

In one embodiment, an average value, i.e., a first average value W1, of channel width (or width of a source/drain region corresponding to the channel width) of each MOS transistor P11, P21, N11, N21, P1m, P2m, N1m, and N2m included in each of the edge sense amplifiers 121-1 and 121-m is greater than an average value, i.e., a second average value W2, of channel width (or width of a gate electrode corresponding to the channel width) of each MOS transistor included in each of the inner sense amplifiers 121-2 to 121-(m-1). For example, the transistors P11, P21, N11, and N21 that make up a first edge sense amplifier 121-1 may have a first average channel width among those transistors, and the transistors that make up a first inner sense amplifier 121-2 may have a second average channel width among those transistors. The first channel width may be greater than the second channel width. Alternatively, or additionally, when the entire sense amplifier array is taken as a whole, the average channel width per transistor for all of the transistors that form the edge sense amplifiers may be greater than the average channel width per transistor for all of the transistors that form the inner sense amplifiers.

In one embodiment, the first average value W1 may be greater than the second average value W2 by 10% or more, for example. The value of 10% is exemplary only. In certain embodiments, an intentional average value difference may be selected to be an amount greater than any expected process variation, to ensure that all edge sense amplifiers have greater average channel width than all inner sense amplifiers. For example, the above value of 10% may be used when a known process variation is as high as +/−4%. However, should a known process variation only cause variations of, for example, +/−2%, then an intentional average size increase less than 10% may be used (e.g., 5%). In one embodiment, each transistor of the edge sense amplifiers 121-1 to 121-m has a larger size than any transistor of the inner sense amplifiers 121-2 to 121-(m-1), by the designated percentage (e.g., 10%). In one embodiment, a design parameter may be set such that even after process variations are accounted for, the average values, or the transistor sizes discussed above in the edge sense amplifiers are at least a certain percentage (e.g., 10%) larger than the average values or transistor sizes of the inner sense amplifiers.

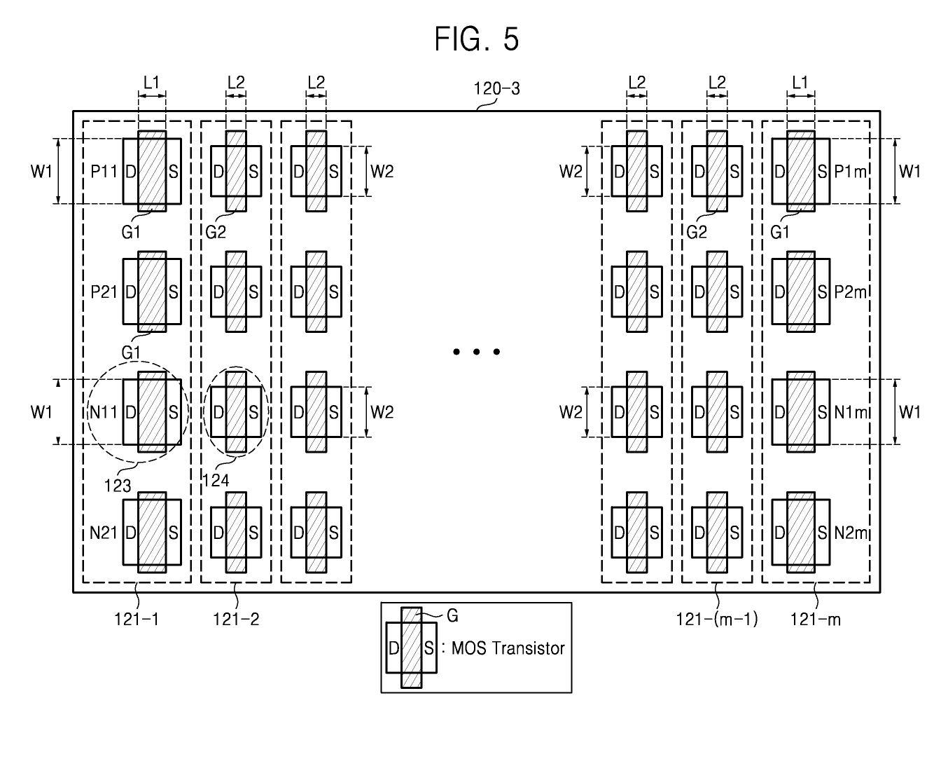

FIG. 5 is a plan view illustrating still another example embodiment of the sense amplifier array illustrated in FIG. 2A or 2B.

As illustrated in FIG. 5, an average value L1 of a channel length of each MOS transistor P11, P21, N11, N21, P1m, P2m, N1m and N2m, which is included in each of the edge sense amplifiers 121-1 and 121-m included in a sense amplifier array 120-3, is greater than an average value L2 of a channel length of each MOS transistor, which is included in each of the inner sense amplifiers 121-2 to 121-(m-1).

Additionally, an average value W1 of a channel width of each MOS transistor P11, P21, N11, N21, P1m, P2m, N1m and N2m, which is included in each of the edge sense amplifiers 121-1 and 121-m included in a sense amplifier array 120-3, is greater than an average value W2 of a channel width of each MOS transistor, which is included in each of the inner sense amplifiers 121-2 to 121-(m-1).

In the examples of FIGS. 3-5, based on the channel widths and/or lengths of the transistors that make up the different sense amplifiers, an average area of the channel for edge sense amplifiers may be a certain amount larger than the average area of the channels for inner sense amplifiers. In one embodiment, the average area for the edge sense amplifiers may be greater than the average area of the channels for the inner sense amplifiers by 10% or more, for example. As in the example above, the value of 10% is exemplary only. In certain embodiments, an intentional average area difference may be selected to be an amount greater than any expected process variation, to ensure that all edge sense amplifiers have greater average channel area than all inner sense amplifiers. For example, the above value of 10% may be used when a known process variation is as high as +/−4%. However, should a known process variation only cause variations of, for example, +/−2%, then an intentional average area increase less than 10% may be used (e.g., 5%). In one embodiment, each transistor of the edge sense amplifiers 121-1 to 121-m has a larger channel area than any transistor of the inner sense amplifiers 121-2 to 121-(m-1), by the designated percentage (e.g., 10%). In one embodiment, a design parameter may be set such that even after process variations are accounted for, the average channel area discussed above in the edge sense amplifiers is at least a certain percentage (e.g., 10%) larger than the average channel area of the inner sense amplifiers.

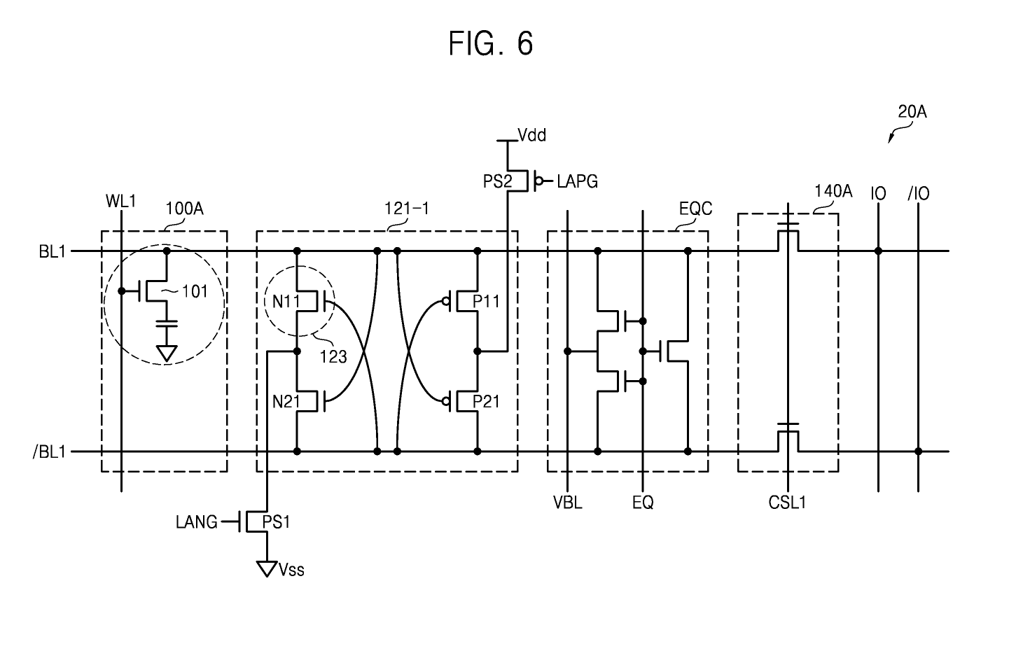

FIG. 6 illustrates a part of a memory device including an edge sense amplifier included in the sense amplifier array illustrated in FIG. 3, 4, or 5, according to one embodiment.

An operation of a part 20A of a memory device 20 or 20-1 (collectively: 20) is explained referring to FIGS. 1 to 6.

A normal memory cell 101 included in a part 100A of a memory cell array 100 is connected to a first word line WL1 and a first bit line BL1. An edge sense amplifier 121-1 is connected to a first bit line BL1 and a first complementary bit line/BL1, and senses and amplifies a voltage difference between the first bit line BL1 and the first complementary bit line/BL1.

The edge sense amplifier 121-1 includes an N-channel sense amplifier and a P-channel sense amplifier. The N-channel sense amplifier includes N-channel MOS transistors N11 and N21, and the P-channel sense amplifier includes P-channel MOS transistors P11 and P21.

During a pre-charge operation, an equalization circuit EQC pre-charges the first bit line BL1 and the first complementary bit line/BL1 with an equalization voltage VBL in response to an equalization enable signal EQ.

During an amplification operation, a first power supply circuit PS1 supplies a ground voltage Vss to a common node of N-channel MOS transistors N11 and N21 in response to an N-channel sense amplifier enable signal LANG having a high level. During the amplification operation, a second power supply circuit PS2 supplies a supply voltage Vdd to a common node of P-channel MOS transistors P11 and P21 in response to a P-channel sense amplifier enable signal LAPG having a low level.

Accordingly, during the amplification operation, the edge sense amplifier 121-1 senses and amplifies a signal stored in a normal memory cell 101 based on a difference between a voltage of the first bit line BL1 and a voltage of the first complementary bit line/BL1.

The edge sense amplifier 121-1 may include each component EQC, PS1 and PS2; however, for convenience of explanation, each component 121-1, EQC, PS1 and PS2 is divided and illustrated. A part 140A of the output gate circuit 140 may transmit signals of a bit line pair BL1 and /BL1 to an input/output line pair IO and /IO based on a column selection signal CSL1 having a high level.

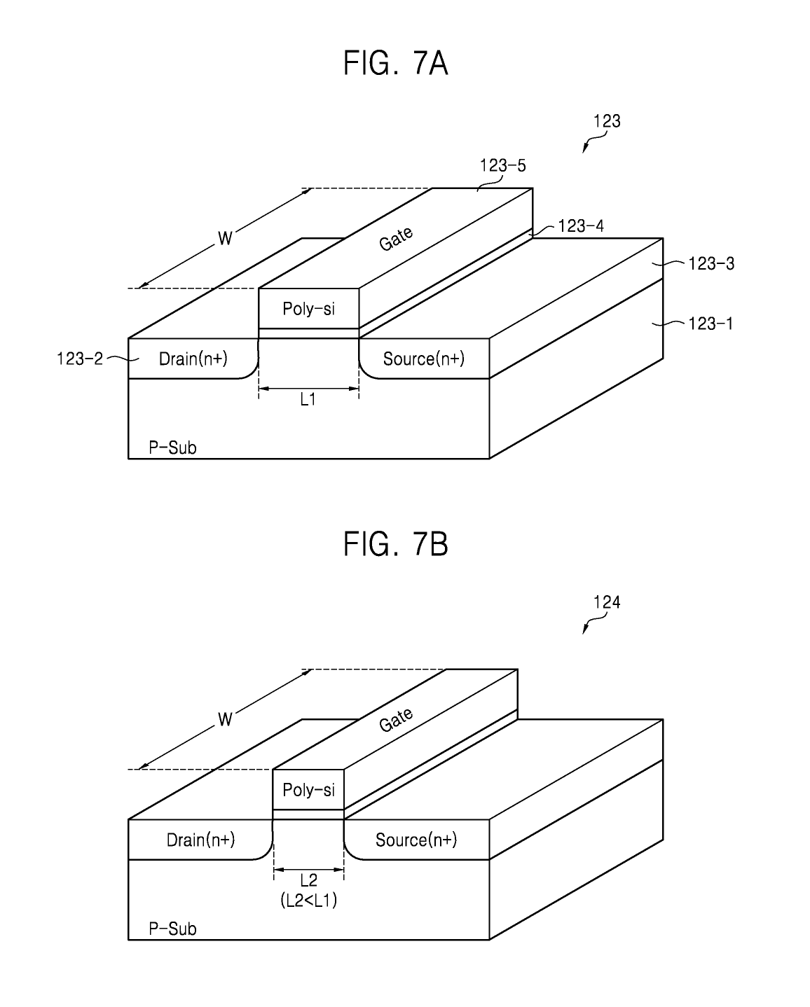

FIGS. 7A and 7B illustrate a cross-sectional diagram of N-channel MOS transistors included in a sense amplifier array illustrated in FIG. 3, according to one exemplary embodiment. Referring to FIGS. 3, 6, 7A and 7B, an N-channel MOS transistor 123 included in the edge sense amplifier 121-1 includes a drain 123-2 and a source 123-3 formed inside a P-type substrate 123-1, an oxide film 123-4 formed on the P-type substrate 123-1, and a gate electrode 123-5 formed on the oxide film 123-4. The N-channel MOS transistor 123 has a channel length L1 and a channel width W.

Except for a channel length L2, (e.g., layout, shape, and size) a structure of an N-channel transistor 124 included in a inner sense amplifier 121-2 illustrated in FIG. 7B is substantially the same as a structure of the N-channel MOS transistor 123 included in the edge sense amplifier 121-1 illustrated in FIG. 7A. Referring to FIGS. 7A and 7B, in one embodiment, a channel length L1 of the N-channel MOS transistor 123 is longer than a channel length L2 of the N-channel MOS transistor 124 (e.g., by more than 10%).

A gate electrode 123-5 may be embodied, for example, in metal or poly-silicon.

‘D’ of FIG. 3 depicts a drain or a drain region of a MOS transistor, ‘S’ depicts a source or a source region of the MOS transistor, and ‘G’, ‘G1’ and ‘G2’ depict a gate electrode corresponding to a channel length of a corresponding MOS transistor, respectively. Here, since a channel length L1 of each MOS transistor, included in each edge sense amplifier 121-1 and 121-m, is longer than a channel length L2 of each MOS transistor, included in the inner sense amplifier 121-2 to 121-(m-1), a length of a gate electrode G1 corresponding to the channel length L1 is longer than a length of a gate electrode G2 corresponding to the channel length L2.

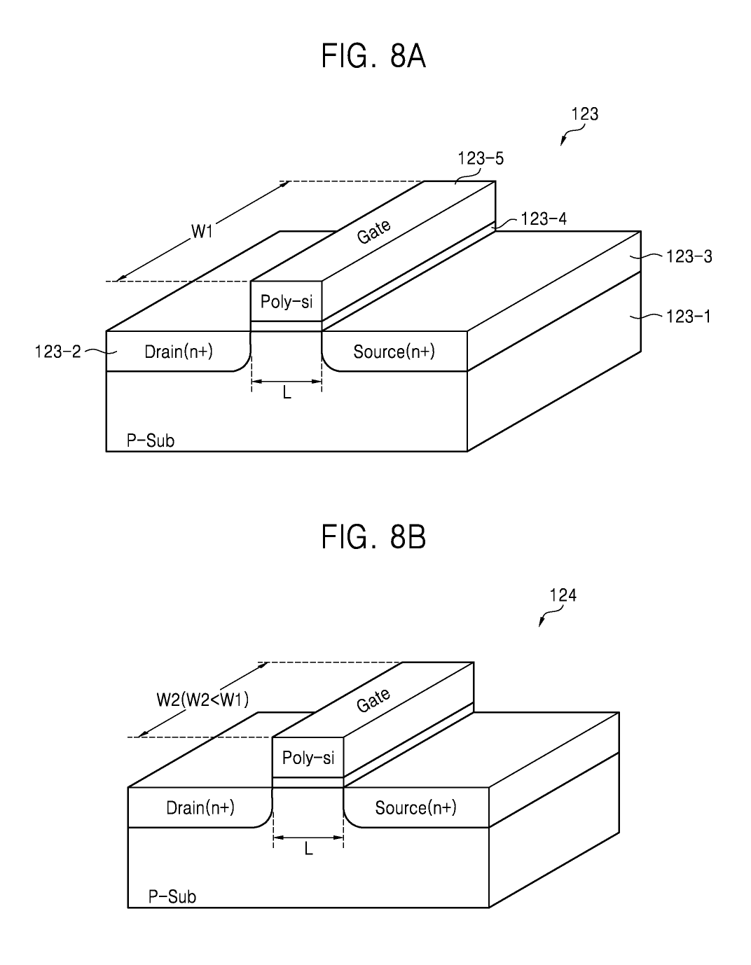

FIGS. 8A and 8B illustrate a cross-sectional diagram of N-channel MOS transistors included in the sense amplifier array illustrated in FIG. 4, according to certain exemplary embodiments. Referring to FIGS. 4, 8A and 8B, a channel width W1 of the N-channel MOS transistor 123 of an edge sense amplifier 121-1 illustrated in FIG. 8A is wider than a channel width W2 of the N-channel MOS transistor 124 of a inner sense amplifier 121-2 illustrated in FIG. 8B (e.g., by more than 10%).

According to an example embodiment, a channel length and a channel width of each MOS transistor included in each edge sense amplifier 121-1 and 121-m may be formed greater than a channel length and a channel width of each MOS transistor included in each inner sense amplifier 121-1 and 121-(m-1).

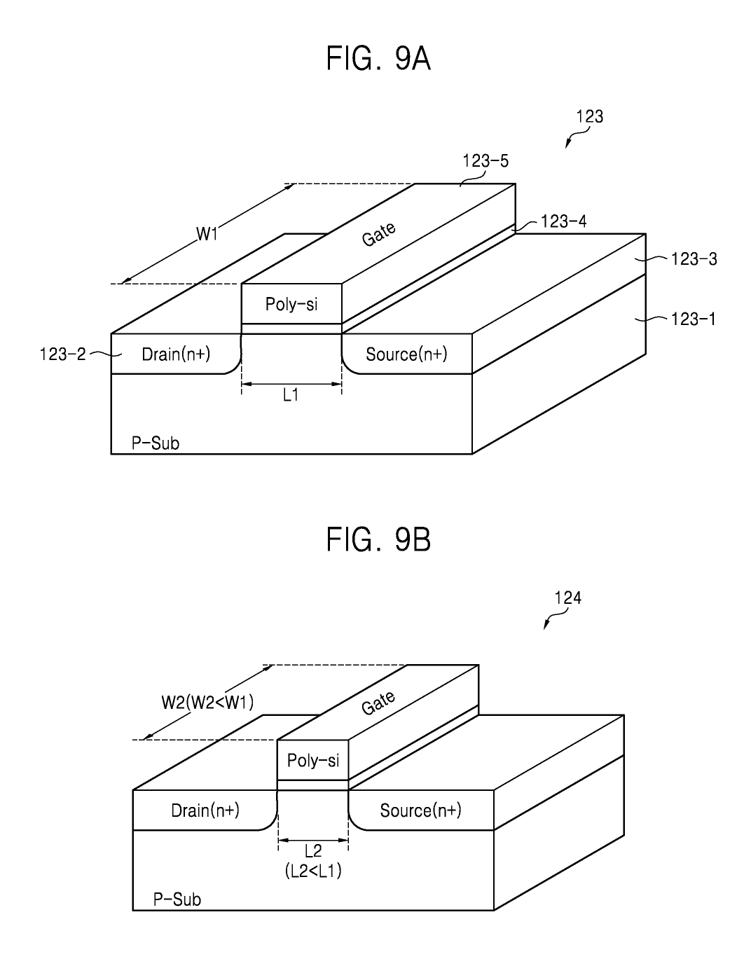

FIGS. 9A and 9B illustrate a cross-sectional diagram of N-channel MOS transistors included in the sense amplifier array illustrated in FIG. 5. Referring to FIGS. 5, 9A and 9B, a channel length L1 and a channel width W1 of the N-channel MOS transistor 123 of the edge sense amplifier 121-1 illustrated in FIG. 9A are respectively greater than a channel length L2 and a channel width W2 of the N-channel MOS transistor 124 of the inner sense amplifier 121-2 illustrated in FIG. 9B. For example, L1 may be greater than L2 by more than 10%, and W1 may be greater than W2 by more than 10%. Alternatively, or additionally, the combined area based on L1 and W1 may be greater than the combined area based on L2 and W2 by more than 10% or some other designated intentionally-set size.

Each channel length L, L1 and L2, each channel width W, W1 and W2, and each gate electrode G1 and G2 illustrated in FIGS. 3 through 9B depict characteristics that reflect a desired relative size. The actual size of the depicted elements may vary, likely due to process variations that occur in a process of manufacturing the memory device. Therefore, the uniformity in size in the figures may reflect an an average actual value for a set of elements, wherein each element as actually manufactured may vary within a particular size range.

As explained referring to FIGS. 1 through 9B, when the size of each MOS transistor included in each edge sense amplifier 121-1 and 121-m is laid out greater than the size of each MOS transistor included in each inner sense amplifier 121-2 to 121-(m-1), distribution of attributes (or characteristics), e.g., a threshold voltage, an on-state saturation current or an off-state leakage current, of each of MOS transistors, included in each of the edge sense amplifier 121-1 and 121-m, gets decreased compared to distribution of attributes of each of MOS transistors included in each of the inner sense amplifiers 121-2 to 121-(m-1).

Accordingly, a sensing capability of each edge sense amplifier 121-1 and 121-m gets improved further than a sensing capability of each inner sense amplifier 121-2 to 121-(m-1). This counteracts an effect that often occurs at edge sense amplifiers where the process variation tends to be higher than the process variation of inner sense amplifiers. Accordingly, a yield of a device 10 or 20 may increase.

Although the above-described figures depict a sense amplifier array for a memory cell array, this is just one example embodiment. For example, a memory cell array may have a plurality of sense amplifier arrays included throughout (e.g., bit lines could be separated in to groups so that certain sense amplifier arrays are used to sense data in cells for sub-portions of a bit line). In one embodiment, for example, sub-bit lines can be used, such that a plurality of sense amplifier arrays are used that correspond to the number of sub-bit lines in each bit line. As such, certain sense amplifiers may be global sense amplifiers, while others may be local sense amplifiers.

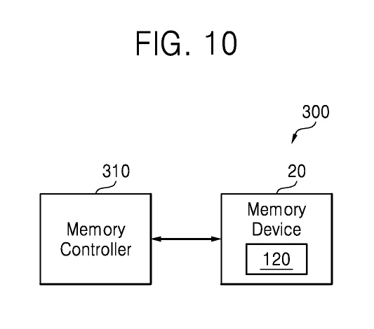

FIGS. 10 through 20 illustrate example embodiments of systems that may include the memory device illustrated in FIG. 2A or 2B. Referring to FIG. 10, a system 300 includes the memory device 20 including the sense amplifier array 120, and a memory controller 310. The system 300 may be embodied in a multi-chip module or a system on chip. The memory controller 310 may control an operation of the memory device 20.

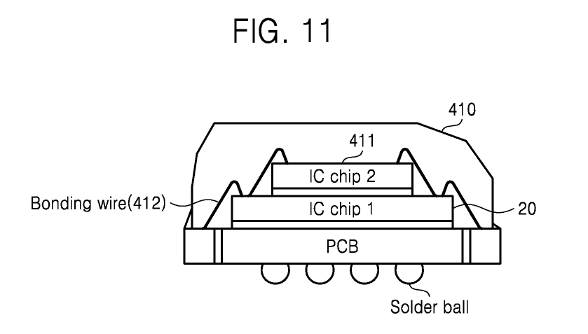

FIG. 11 is an example of a system including the memory device 20 or 20-1 (collectively: 20) illustrated in FIG. 2A or 2B, e.g., a semiconductor package 410. The semiconductor package 410 may further include a memory controller 411 for controlling an operation of the memory device 20. According to an example embodiment, unlike a structure illustrated in FIG. 11, the memory device 20 may be stacked on an upper side of the memory controller 411 (e.g., the memory device 20 may either be between a memory controller 411 and a PCB, or may be above both the memory controller and the PCB).

The memory controller 411 may be, for example, a processor. In one embodiment, each device 20 and 411 may be connected to a printed circuit board (PCB) through bonding wires 412. The PCB may communicate with another device through solder balls.

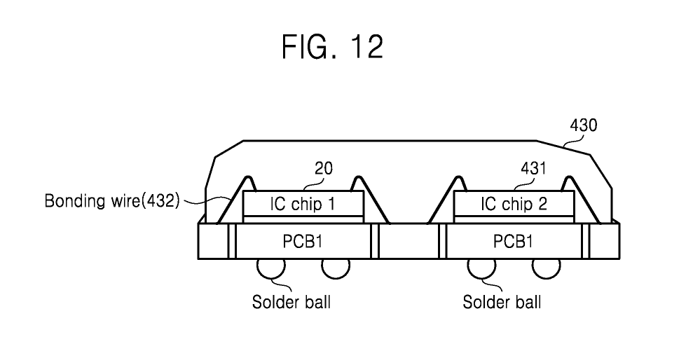

FIG. 12 is an example of a system including the memory device 20 illustrated in FIG. 2A or 2B, e.g., a semiconductor package 430. The semiconductor package 430 may further include a memory controller 431 for controlling an operation of the memory device 20.

Here, the memory controller 431 may be a processor. Each device 20 and 431 may be connected to each printed circuit board PCB1 and PCB2 through each bonding wire 432. Each printed circuit board PCB1 and PCB2 may communicate with another device through solder balls. Each printed circuit board PCB1 and PCB2 may be embodied in a single printed circuit board.

The memory device 20 illustrated in FIG. 2A or 2B may be packaged in a package such as Package On Package (PoP), Ball Grid Arrays (BGAs), Chip Scale Packages (CSPs), Plastic Leaded Chip Carrier (PLCC), Plastic Dual In-Line Package (PDIP), Chip On Board (COB), CERamic Dual In-Line Package (CERDIP), plastic metric quad flat pack (MQFP), Thin Quad Flat Pack (TQFP), small-outline integrated circuit (SOIC), shrink small outline package (SSOP), thin small outline (TSOP), system in package (SIP), multi chip package (MCP), wafer-level package (WLP), or wafer-level processed stack package (WSP) or the like.

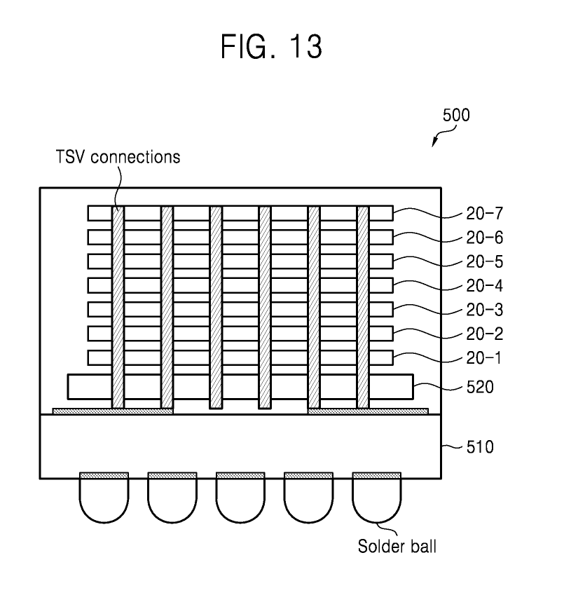

As illustrated in FIG. 13, memory devices 20-1 through 20-7 may be stacked in a stacked semiconductor chip package. In one embodiment, the memory devices 20-1 through 20-7 are stacked on a logic layer 520. The logic layer 520 may be stacked on a package substrate 510. Here, a structure and an operation of each of the memory devices 20-1 through 20-7 may be substantially the same as a structure and an operation of semiconductor device 20 or 20-1 explained referring to FIGS. 1 through 9.

Each device 20-1 to 20-7, 520 and 510 may be connected to each other through vertical electrical connection means, e.g., through substrate vias (TSVs, such as through silicon vias). According to an example embodiment, at least one of memory devices 20-2 to 20-7 may be replaced with a memory controller or a processor, which may control an operation of the memory device 20-1.

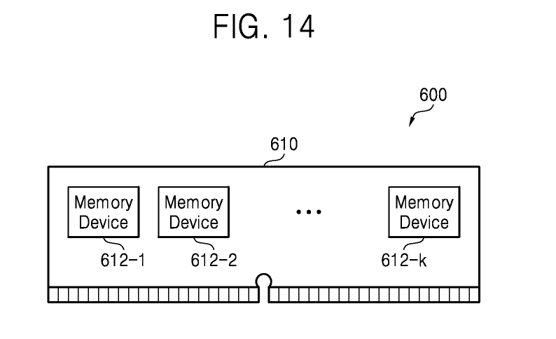

As illustrated in FIG. 14, an exemplary system 600, e.g., a memory module, includes memory devices 612-1 through 612-k, where k is a natural number, mounted on a PCB 610. A structure and an operation of each of the memory devices 612-1 through 612-k are substantially the same as a structure and an operation of the memory device 20 or 20-1 explained referring to FIGS. 1 through 9.

The memory module may be, for example, a single in-line memory module (SIMM), a dual in-line memory module (DIMM), a single in-line pin package (SIPP) memory, or a small outline DIMM (SO-DIMM).

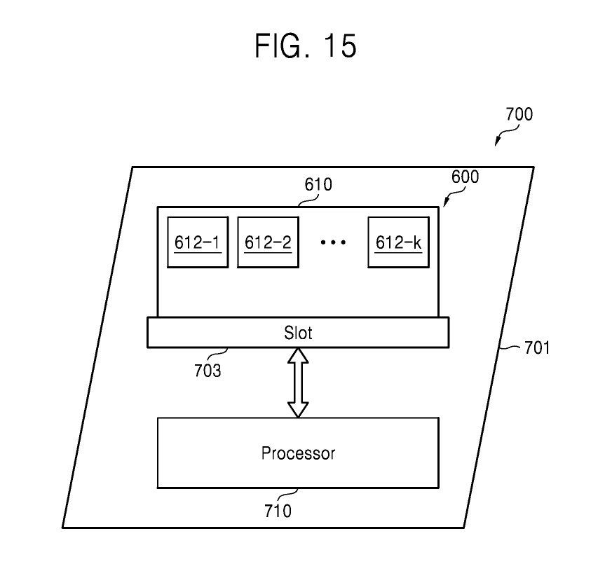

As illustrated in FIG. 15, a system 700 may be embodied, for example, in a personal computer (PC), a laptop computer, or a server. The system 700 includes a slot 703 and a processor 710 which are installed in a main board 701. Each of the memory devices 612-1 to 612-k of a memory module 600 may transmit or receive data with the processor 710 through the slot 703 and the main board 701. The processor 710 may be a chipset.

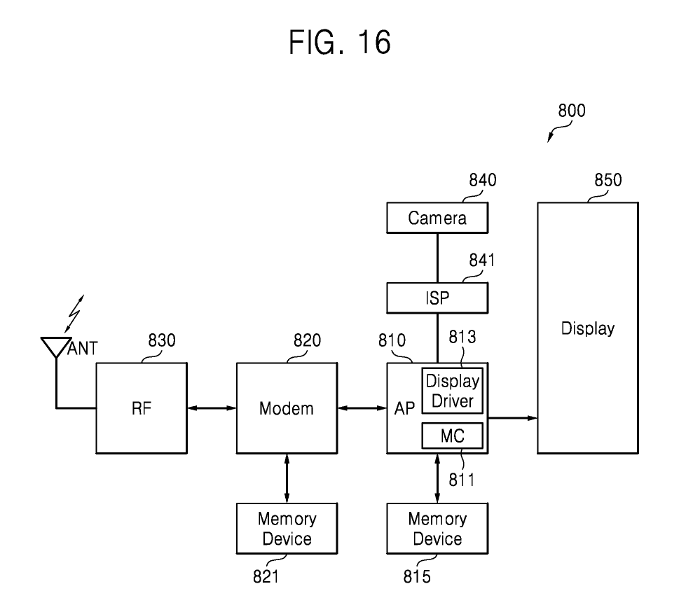

As illustrated in FIG. 16, a system 800 may be embodied in a mobile computing device. The mobile computing device may be embodied, for example, in a laptop computer, a mobile phone, a smart phone, a tablet PC, a personal digital assistant (PDA), an enterprise digital assistant (EDA), a digital still camera, a portable multimedia player (PMP), a personal navigation device or portable navigation device (PND), a handheld game console, or an e-book.

An application processor (AP) 810, e.g., a mobile application processor 810, may control an operation of each element 815, 820, 841 and 850.

A structure and an operation of each memory device 815 and 821 are substantially the same as a structure and an operation of the memory device 20 or 20-1 explained referring to FIGS. 1 through 9.

The memory controller 811 embodied inside the application processor 810 may control an access operation on the memory device 815. A display driver 813 embodied inside the application processor 810 may control an operation of a display 850. The display 850 may be embodied in a Thin film transistor liquid crystal display (TFT-LCD), a light-emitting diode (LED) display, an organic LED (OLED) display, an active-matrix OLED (AMOLED) display, or a flexible display.

A modem 820 may interface data transmitted or received between a radio transceiver 830 and the application processor 810. Data processed by the modem 820 may be stored in the memory device 821 or transmitted to the application processor 810.

Radio data received through an antenna ANT are transmitted to the modem 820 through the radio transceiver 830, data output from the modem 820 are converted into radio data by the radio transceiver 830, and converted radio data are output through the antenna ANT.

An image signal processor 841 may process a signal output from a camera (or an image sensor 840) and transmit processed data to the application processor 810.

The application processor 810 may control execution of at least one of web browsing, e-mail access, video playback, document editing and image editing.

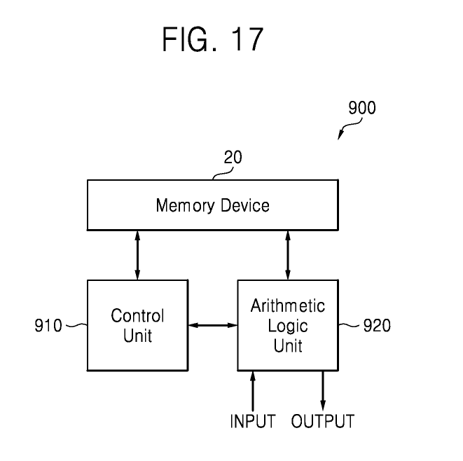

As illustrated in FIG. 17, a system 900 may be embodied in a processor.

The processor 900 includes the memory device 20, a control unit 910, and an arithmetic-logic unit (ALU) 920.

According to a control of the control unit 910, the ALU 920 may perform an arithmetic operation and/or a logical operation on input data INPUT and store a result of the performance in the memory device 20. In addition, according to a control of the control unit 910, the ALU 920 may perform an arithmetic operation and/or a logical operation on input data INPUT and data output from the memory device 20, and store a result of the performance in the memory device 20 or output it as output data OUTPUT.

For example, the ALU 920 may perform a bitwise logical operation, e.g., an AND operation, a NOT operation, an OR operation, a NAND operation or a XOR operation.

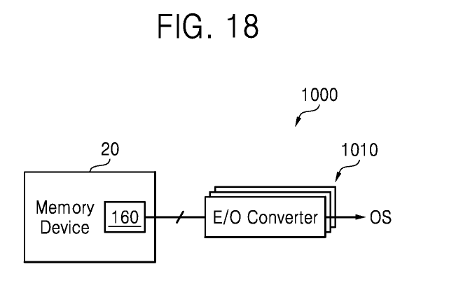

As illustrated in FIG. 18, a system 1000 includes the memory device 20 and an electric optical conversion block 1010. The electric-optical conversion block 1010 may include electric-optical converters, and the electric-optical converters convert electrical signals output from output drivers embodied in the output driver block 160 into optical signals and output converted optical signals OS.

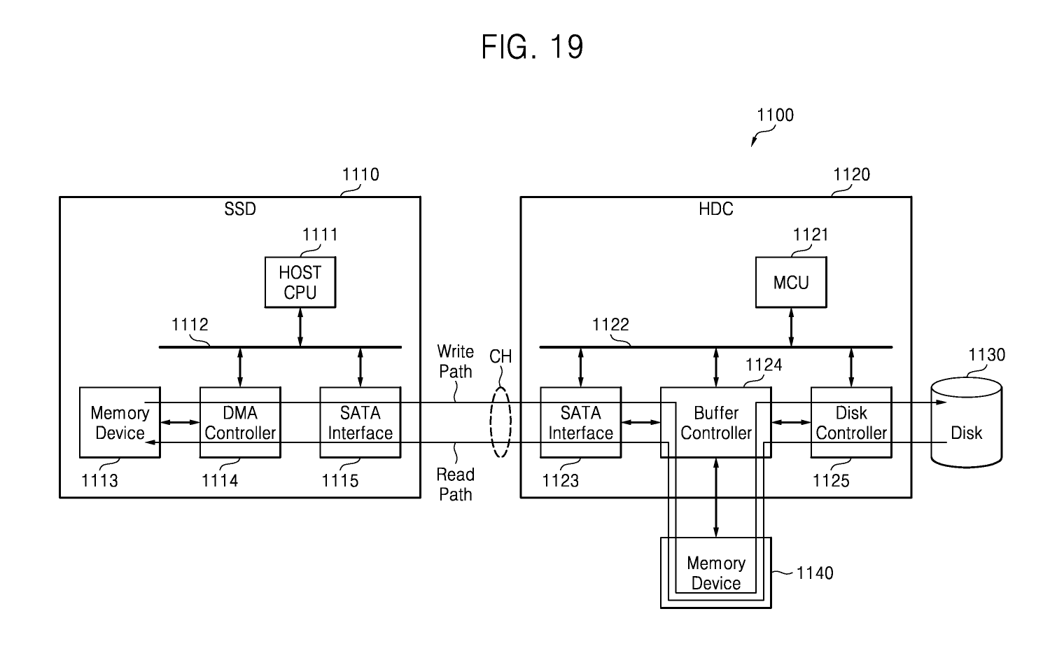

As illustrated in FIG. 19, a computing system 1100 includes a host 1110, a hard disk controller 1120, a hard disk 1130 and a memory device 1140. A hard disk drive may include the hard disk controller 1120 and the hard disk 1130.

A structure and an operation of each memory device 1113 and 1140 are substantially the same as a structure and an operation of the memory device 20 explained referring to FIGS. 1 to 9. During a write operation, data output from the memory device 1113 are written in the hard disk 1130 through a write path.

According to a control of a direct memory access (DMA) controller 1114 or a host CPU 1111, data output from the memory device 1113 are transmitted to a device SATA interface 1123 through a host SATA interface 1115 and a channel CH. Each element 1111, 1113, 1114 and 1115 may communicate with each other through a bus 1112.

According to a control of a main control unit 1121, a buffer controller 1124 stores data output from the device SATA interface 1123 in a memory device 1140. According to a control of the buffer controller 1124, data output from the memory device 1140 are transmitted to a disk controller 1125. The disk controller 1125 stores data output from the buffer controller 1124 in the hard disk 1130. Each element 1121, 1123, 1124 and 1125 may communicate with each other through a bus 1122.

During a read operation, data output from the disk 1130 may be stored in the memory device 1113 through a read path.

According to a control of the main control unit 1121, the disk controller 1125 transmits data stored in the hard disk 1130 to the buffer controller 1124. According to a control of the main control unit 1121, the buffer controller 1124 stores data output from the disk controller 1125 in the memory device 1140. According to a control of the main control unit 1121, the buffer controller 1124 transmits data stored in the memory device 1140 to a SATA interface 1115 through the device SATA interface 1123 and the channel CH.

According to a control of the direct memory access (DMA) controller 1114 or the host CPU 1111, data input through the SATA interface 1115 are stored in the memory device 1113. Accordingly, the host CPU 1111 may read data stored in the memory device 1113.

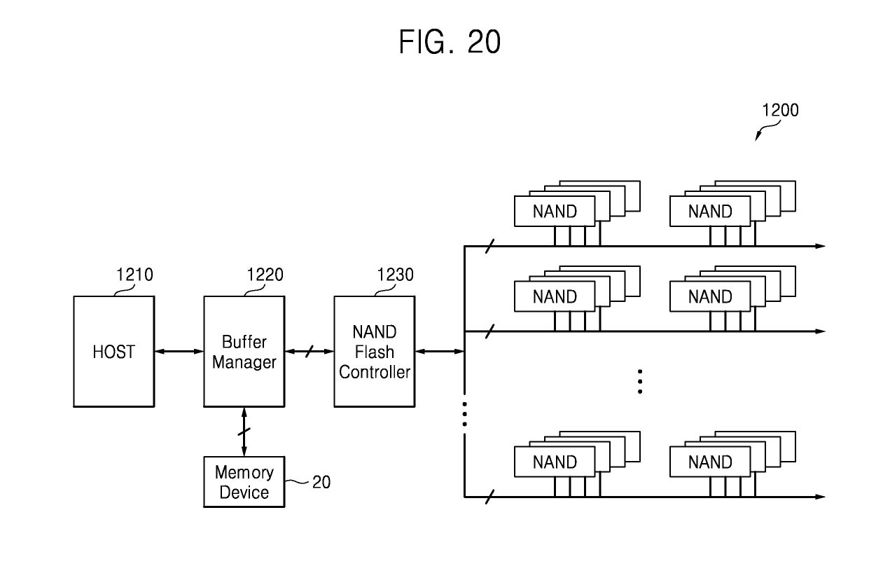

As illustrated in FIG. 20, a system 1200 may be embodied in a solid state drive (SSD). The system 1200 includes the memory device 20, a host 1210, a buffer manager 1220, a NAND flash memory controller 1230 and NAND flash memory devices NAND.

The NAND flash memory controller 1230 may control a data processing operation, e.g., a program operation, a read operation or an erase operation, of each of the NAND flash memory devices NAND.

The buffer manager 1220 may control storage of data transmitted or received between the host 1210 and the NAND flash memory controller 1230 in the memory device 20. Here, the buffer manager 1220 may include a memory controller. However, the memory controller may be embodied outside the buffer manager 1220.

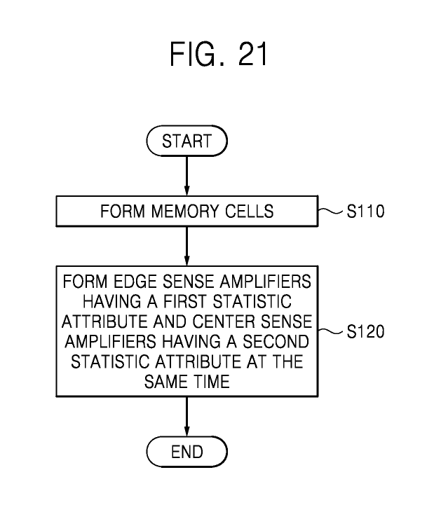

FIG. 21 is a flowchart depicting a method of manufacturing the memory device illustrated in FIG. 2A or 2B. Referring to FIGS. 1 to 9B, and 21, a memory cell array 100 including first normal memory cells and second normal memory cells is formed inside and/or on a semiconductor substrate (S110). Each of the first normal memory cells and the second normal memory cells may refer to, for example, a normal memory cell 101. The descriptions herein may apply to redundant memory cells as well. However, in certain embodiments, sense amplifier arrays using different-sized sense amplifiers are used either for a set of all normal memory cells, or for a set of all redundant cells.

The edge sense amplifiers 121-1 and 121-m each having a first statistic attribute to amplify a signal output from each of the first normal memory cells, and the inner sense amplifiers 121-2 to 121-(m-1) each having a second statistic attribute to amplify a signal output from each of the second normal memory cells are formed inside and/or on a semiconductor substrate at the same time (S 120). According to an example embodiment, dummy sense amplifier regions 120A and 120B may be formed inside and/or on the semiconductor substrate.

For convenience of explanation, each step S110 and S120 is divided from each other in FIG. 21; however, each step S110 and S120 may be formed at the same time by using one mask.

According to the different figures above, the statistic attributes may refer to different aspects related to a size of a sense amplifier or elements of the sense amplifier.

For example, as explained referring to FIGS. 3, 7A and 7B, the first statistic attribute may be determined according to an average length of MOS transistors included in the edge sense amplifiers 121-1 and 121-m, e.g., a first average channel length L1, and the second statistic attribute may be determined according to an average length of MOS transistors included in the inner sense amplifiers 121-2 to 121-(m-1), e.g., a second average channel length L2. In one embodiment, the first average channel length L1 is longer than a second average channel length L2 by more than 10%.

In addition, as explained referring to FIGS. 4, 8A and 8B, the first statistic attribute may be determined according to an average width of MOS transistors included in the edge sense amplifiers 121-1 and 121-m, e.g., a first average channel width W1, and the second statistic attribute may be determined according to an average width of MOS transistors included in the inner sense amplifiers 121-2 to 121-(m-1), e.g., a second average channel width W2. In one embodiment, the first average channel width W1 is wider than the second average channel width W2 by more than 10%.

In addition, as explained referring to FIGS. 5, 9A and 9B, the first statistic attribute may be determined according to a first average channel length L1 and a first average channel width W1 of MOS transistors included in the edge sense amplifiers 121-1 and 121-m, and the second statistic attribute may be determined according to a second average channel length L2 and a second average channel width W2 of MOS transistors included in the inner sense amplifiers 121-2 to 121-(m-1).

Here, in one embodiment, the first average channel length L1 may be longer than the second average channel length L2 by more than 10%, and the first average channel width W1 may be wider than the second average channel width W2 by more than 10%. Alternatively, or additionally, the average channel area for the MOS transistors included in the edge sense amplifiers 121-1 and 121-m may be more than 10% of the average channel area of the MOS transistors included in the inner sense amplifiers 121-2 to 121-(m-1).

As each of sense amplifiers having different sizes based on a layout location has a different sensing capability, a signal output from a memory cell embodied at an edge of a memory cell array may be correctly sensed.

Accordingly, a yield of a memory device including the sense amplifiers may increase.

1. A memory device, comprising:
a memory cell array including memory cells arranged in a matrix; and
a sense amplifier array including a plurality of sense amplifiers, each sense amplifier configured to amplify a signal output from each cell of a set of memory cells;
wherein each sense amplifier of the sense amplifier array is formed of a plurality of transistors, and
wherein an average size among the plurality of transistors that form a first sense amplifier of the sense amplifier array is larger than an average size among the plurality of transistors that form a second sense amplifier of the sense amplifier array.

2. The memory device of claim 1, wherein the first sense amplifier is an edge sense amplifier, and the second sense amplifier is an inner sense amplifier.

3. The memory device of claim 1, wherein an average channel length among the plurality of transistors that form the first sense amplifier of the sense amplifier array is larger than an average channel length among the plurality of transistors that form the second sense amplifier of the sense amplifier array.

4. The memory device of claim 1, wherein an average channel width among the plurality of transistors that form the first sense amplifier of the sense amplifier array is larger than an average channel width among the plurality of transistors that form the second sense amplifier of the sense amplifier array.

5. (canceled)

6. (canceled)

7. The memory device of claim 1, wherein an average channel area among the plurality of transistors that form the first sense amplifier of the sense amplifier array is larger than an average channel area among the plurality of transistors that form the second sense amplifier of the sense amplifier array.

8. The memory device of claim 1, wherein the average size among the plurality of transistors that form the first sense amplifier of the sense amplifier array is at least 10% larger than the average size among the plurality of transistors that form the second sense amplifier of the sense amplifier array.

9. A memory device, comprising:
a memory cell array including memory cells arranged in rows and columns;
a sense amplifier array including a plurality of sense amplifiers, each sense amplifier configured to amplify a signal output from at least part of a column of memory cells;
wherein each sense amplifier of the sense amplifier array is formed of a plurality of transistors, and
wherein a difference in average size between the plurality of transistors that form a first sense amplifier of the sense amplifier array and the plurality of transistors that form a second sense amplifier of the sense amplifier array is greater than a difference in average size between the plurality of transistors that form the second sense amplifier of the sense amplifier array and the plurality of transistors that form a third sense amplifier of the sense amplifier array.

10. The memory device of claim 9, wherein the first sense amplifier is an edge sense amplifier and second and third sense amplifiers are each inner sense amplifiers.

11. (canceled)

12. (canceled)

13. The memory device of claim 9, wherein the difference in average size between the plurality of transistors that form the first sense amplifier of the sense amplifier array and the plurality of transistors that form the second sense amplifier of the sense amplifier array is due to one or more of:
average channel length of the plurality of transistors that form the first sense amplifier being different from average channel length of the plurality of transistors that form the second sense amplifier; and
average channel width of the plurality of transistors that form the first sense amplifier being different from average channel width of the plurality of transistors that form the second sense amplifier.

14. The memory device of claim 9, wherein the difference in average size between the plurality of transistors that form the first sense amplifier of the sense amplifier array and the plurality of transistors that form the second sense amplifier of the sense amplifier array is at least 10%.

15. A memory device, comprising:
a memory cell array including normal memory cells arranged in a matrix; and
a sense amplifier array including sense amplifiers each configured to amplify a signal output from each memory cell of a set of the normal memory cells,
wherein a first set of the sense amplifiers have different sizes than a second set of the sense amplifiers, so that different sense amplifiers have different sensing capabilities based on a layout location.

16. The memory device of claim 15, wherein the sizes of the sense amplifiers of the first set differ from the sizes of the sense amplifiers of the second set according to at least one of a channel length and a channel width of a MOS transistor included in each of the respective sense amplifiers.

17. The memory device of claim 15, wherein the sense amplifier array includes two edge sense amplifiers, each located at an edge of the sense amplifier array, and inner sense amplifiers located between the edge sense amplifiers, wherein an average element size of a set of first amplification elements included in each of the edge sense amplifiers, is greater than an average element size of a set of second amplification elements included in each of the inner sense amplifiers.

18. The memory device of claim 17, wherein the average element size of the set of first amplification elements is greater than the average element size of the set of second amplification elements by more than 10%.

19. The memory device of claim 17, wherein the average element size of the set of first amplification elements and the average element size of the set of second amplification elements vary according to channel lengths of at least one of an N-channel MOS transistor and a P-channel MOS transistor included in a corresponding sense amplifier.

20. The memory device of claim 17, wherein the average element size of the set of first amplification elements and the average element size of the set of second amplification elements vary according to channel widths of at least one of an N-channel MOS transistor and a P-channel MOS transistor included in a corresponding sense amplifier.

21. The memory device of claim 15, further comprising dummy sense amplifiers embodied outside the sense amplifier array.

22. The memory device of claim 15, wherein the memory cell array is part of three-dimensionally stacked memory cell arrays, the arrays in the stack connected to each other through vertical electrical connectors.

23. The memory device of claim 15, wherein the memory device is a semiconductor chip.

24. (canceled)

25. The memory device of claim 15, further comprising:
a printed circuit board (PCB) that is part of a memory module, wherein the memory device is mounted on the PCB.

26. The memory device of claim 25, wherein the memory module is one of single in-line memory module (SIMM), a dual in-line memory module (DIMM), a single in-line pin package (SIPP) memory, and a small outline DIMM (SO-DIMM).

27. A system, comprising:
a memory device; and
a memory controller for controlling the memory device, wherein the memory device comprises:
a memory cell array including normal memory cells arranged in a matrix; and
a sense amplifier array including sense amplifiers each amplifying a signal output from each cell of a set of normal memory cells, wherein an average element size of first amplification elements, which are included in each of sense amplifiers laid out at edges of the sense amplifier array, is greater than an average element size of second amplification elements, which are included in each of the remaining sense amplifiers of the sense amplifier array.

28. The system of claim 27, wherein a size of the first amplification elements and a size of the second amplification elements differ from each other according to at least one of a channel length and a channel width of at least one of an N-channel MOS transistor and a P-channel MOS transistor included in a corresponding sense amplifier among the sense amplifiers.

29. The system of claim 27, wherein the system is a system on chip (SoC).

30. The system of claim 27, further comprising a processor including the memory controller,
wherein the processor controls performance of at least one of web-browsing, e-mail access, video playback, document editing and image editing.

31. The system of claim 27, further comprising:
an antenna; and
a modem interfacing data transmitted or received between the antenna and the processor,
wherein the system is a mobile computing device.

32. A system of claim 27, wherein the system is a multi-chip module, which includes a first chip including the memory device and a second chip including the memory controller.

33. A method of manufacturing a memory device, comprising:
forming a memory cell array including first normal memory cells and second normal memory cells; and
forming at the same time, edge sense amplifiers each having a first statistic attribute to amplify a signal output from certain of the first normal memory cells and inner sense amplifiers each having a second statistic attribute to amplify a signal output from certain of the second normal memory cells.

34. The method of claim 33, wherein the first statistic attribute includes a first average channel length of MOS transistors included in the edge sense amplifiers,
the second statistic attribute includes a second average channel length of MOS transistors included in the inner sense amplifiers, and
the first average channel length is longer than the second average channel length.

35. The method of claim 33, wherein the first statistic attribute includes a first average channel width of MOS transistors included in the edge sense amplifiers,
the second statistic attribute includes a second average channel width of MOS transistors included in the inner sense amplifiers, and
the first average channel width is wider than the second average channel width.
